(19) United States
(12) Patent Application Publication
(10) Pub. No.: US 2018/0038158 A1
(43) Pub. Date: Feb. 8, 2018

(54) Thermoelectricity Harvested from Infrared Absorbing Coatings

(71) Applicants: Camille Charles Chidiac, Vernon, CA (US); Kailey Rae Bradt, Beverly Hills, CA (US)

(72) Inventors: Camille Charles Chidiac, Vernon, CA (US); Kailey Rae Bradt, Beverly Hills, CA (US)

(21) Appl. No.: 15/666,135

(22) Filed: Aug. 1, 2017

Related U.S. Application Data
(60) Provisional application No. 62/370,120, filed on Aug. 2, 2016.

(51) Int. Cl. E06B 7/28; C03C 17/25; E06B 9/24; C03C 17/00; H01L 35/32; H01L 35/02

(52) U.S. Cl. CPC E06B 7/28; H01L 35/32; H01L 35/02; E06B 9/24; C03C 17/009; C03C 17/25; C03C 2217/219; C03C 2218/118

(57) ABSTRACT

The present invention is a method and device capturing and converting solar heat from infrared absorbing coatings on transparent surfaces, such as glass or polycarbonate, into electricity through the use of at least one thermoelectric generator. This electrical energy can then be used or stored for future access.

### FIELD OF THE INVENTION

A method and device capturing and converting solar heat from infrared absorbing coatings on transparent surfaces, such as glass or polycarbonate, into electricity through the use of at least one thermoelectric generator. This electrical energy can then be used or stored for future access.

### CROSS REFERENCE TO RELATED APPLICATIONS

This application claims the benefit of U.S. Provisional Patent Application No. 62/370,120 filed Aug. 2, 2016, entitled “Thermoelectricity Harvested from Infrared Absorbing Coatings”, the disclosure of which is incorporated by reference herein in its entirety.

### BACKGROUND OF THE INVENTION

The ability to achieve energy saving architectures and optimal solar energy utilization becomes increasingly important as well as affordable. Traditional photovoltaic assemblies of solar cell arrays have become more affordable, especially with government incentives. Solar photovoltaic cell arrays use light energy from the sun to generate electricity through the photovoltaic effect and are typically placed and mounted on rooftops or other surfaces. The majority of modules use crystalline silicone cells doped with impurities resulting in a silicone crystal structure that is typically opaque and thus not suitable for use in windows. Recently, films have been created that are nearly transparent, but still require the light energy to be transported to the sides of a pane of glass where solar energy collection and electric generation can occur, thereby taking up more space and reducing the size of the window pane required to incorporate the solar module electricity generating. In addition, photovoltaic solar cell arrays are generally only used for solar energy production and are not used as thermal insulation.

In addition, recent advances in the use of thermal energy to generate electricity incorporate solar thermal electrical generation in walls, roofs or floors, but not windows due to low visible light transmittance of infrared absorbing materials. Historically, infrared absorbing materials are fixed onto existing surfaces, do not allow for significant visible light transfer, sometimes no visible light transfer, and are not painted onto existing windows or other structures without the need for mounting secondary structures.

Thermal energy transfer through poorly insulated single-pane fenestration is a well-known phenomenon that could serve as a source of renewable energy if the waste heat energy could be captured and converted to electricity. A number of methods have been used to reduce the rate of heat exchange through transparent surfaces, such as various window and door coverings (i.e., curtains, blinds, shutters, plastic, metal, adhesive tint, frit patterns, etc.), various window films, low-e coatings, and even double and triple paned glass. Recent advances in window films and coatings generally rely heavily on the use of infrared reflecting technologies, thereby reflecting the infrared spectrum only when it is warmer outside than it is indoors. This also causes damage to low-e coated double pane glass, as the heat is trapped between the reflective coatings. On the other hand, infrared absorbing technologies, in the form of films and coatings, have allowed for a thermal barrier to be created and act as insulation, while still allowing for significant visible light transfer. In other words, the infrared absorbing films reduce heat transfer while remaining virtually transparent. Semiconductors, such as antimony tin oxide (ATO) and cesium tungsten oxide (CTO) are commonly used in these infrared-absorbing films for their infrared absorption properties in combination with their ability to be formulated into transparent films and coatings. A window insulating film or coating that generates electricity through the capture and conversion of wasted heat energy is needed.

### SUMMARY OF THE INVENTION

The Applicant has found that a pane of float glass or polycarbonate with an insulating coating, which dries to a film (herein “coating” and “film” may be used interchangeably) that absorbs energy in the infrared spectrum connected to a to a thermoelectric generator, as described herein, produces electrical energy and allows for a high visible light transmittance. The resulting product ranges from transparent to slightly tinted. In one embodiment of the present invention, a film that absorbs energy in the infrared (“IR”) spectrum is applied to a pane of float glass or polycarbonate and at least one thermoelectric generating device is connected to said IR absorbing film, thereby capturing and converting the thermal energy absorbed by the coating to electrical energy.

In another embodiment of the present invention, the thermoelectric generating device is connected to a rechargeable electric storage device (such as a lithium ion rechargeable battery) in order to store the converted electrical energy for later use.

In other embodiments, the energy harvested from the waste heat that is converted to electricity by thermoelectric generation can be used to power free standing IoT devices and other electricity-consuming devices (including cooling devices such as small fans or other small cooling units to optimize the temperature differential between the TEG surfaces and thereby optimize energy conversion) and combinations as well as other uses for electrical consumption.

### BRIEF DESCRIPTION OF THE DRAWINGS

FIG. 1 is a partial exploded view of the transparent substrate, preferably glass or polycarbonate, IR absorbing film, unilaterally thermally conductive material and thermoelectric generator (“TEG”).

FIG. 2 shows another view of an embodiment with a thermal switch and electric storage device.

FIG. 3 demonstrates the voltage generation by various IR absorbing films and uncoated glass.

FIG. 4 demonstrates the thermal energy absorption and dissipation of IR absorbing films and uncoated glass.

### DETAILED DESCRIPTION OF THE INVENTION

The opportunity to generate electricity with efficient capture and conversion of waste heat exists in any fenestration. The device and method of harvesting electricity generated using thermal energy captured by an infrared absorbing material applied to a transparent surface, preferably glass or polycarbonate, is not limited to building architectures, but can be used in many applications, including automotive, avionics, and even aerospace applications. Application of an infrared absorbing coating or film can be a retrofit to transparent surfaces or applied to same at the manufacturing level.

Currently, IR-absorbing heat-capturing coatings are used to capture and dissipate thermal energy by absorbing the heat initially absorbed by the transparent substrate, preferably glass or polycarbonate (herein, sometimes referred to simply as “glass”). Specifically, the glass is saturated with heat from exposure of the infrared wavelengths of sunlight, upon which the heat is then transferred from the glass to the IR-absorbing film, whereupon the coating dissipates the heat, thus managing unwanted heat generation. In other words, the IR coating is not used for heat collection, but rather as a thermal barrier only.

In contrast, Applicant uses the IR-absorbing film for thermal electric generation by heat collection and as a thermal barrier. In the preferred embodiment of the invention, the glass is coated with the IR absorbing film and a material with a high thermal conductivity may be placed adjacent to or otherwise connected to the IR absorbing material. The thermal energy captured by the IR absorbing film is thereafter transferred to the high thermal conductive material and directed to the connected heat receiving connection of at least one thermoelectric generator, although in other embodiments the IR absorbing film is connected directly to the heat receiving connection of a thermoelectric generator. High thermal conductive materials may comprise any number of materials, including without limitation graphene, carbon black, carbon nanotube, or any number of metal oxides. Graphene is the high thermal conductive material used in the preferred embodiment of the invention. In addition to fenestrations, applications also include vehicle applications for land, air and water vehicles. In another embodiment of the invention, no conductive material (such as graphene) is used and at least one thermoelectric generator is connected directly to the IR-absorbing film.

Thermoelectric generators convert heat energy to electricity. Thermoelectric generators work using phenomenon in which a temperature difference between two dissimilar electrical conductors or semiconductors produces a voltage difference between the two substances is known as the Seebeck Effect. These two dissimilar electrical conductors comprise a heat receiving connection as well as a heat removal connection of the thermoelectric generator. A phenomenon whereby heat is emitted or absorbed when an electric current passes across a junction between two materials is known as the Peltier Effect. Thermoelectric generators are used to convert temperature differentials to electricity by the use of semiconductors that have high electrical conductivity and low thermal conductivity arranged in a way that p-type and n-type semiconductors can produce a dielectric current that will flow through the generative cell creating a circuit. Advances in thermoelectric generators include thin films, transparency, and flexibility. Herein, the heat receiving connection of a thermoelectric generator is connected to the fenestration and/or substrate and the heat removal connection (and electrical output connection) is connected to various electricity consuming and/or storage devices, depending upon the embodiment of the invention. For simplicity, the electrical output connection of a thermoelectric generator is simply referred to the “heat removal connection” of the thermoelectric generator.

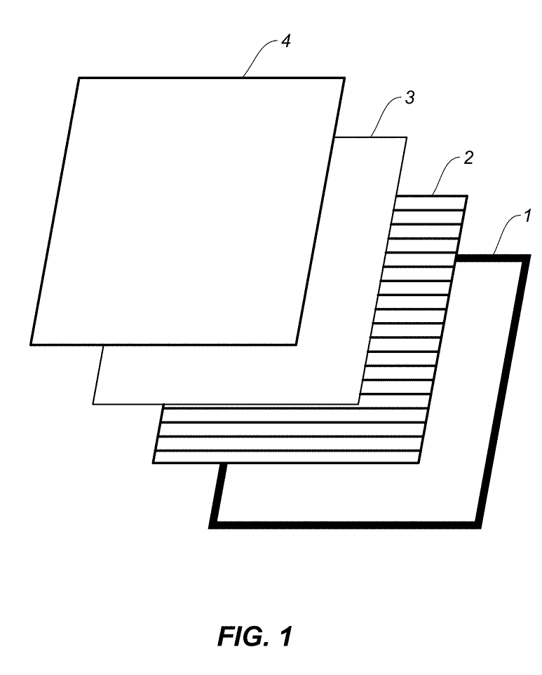

Applicant's FIG. 1 shows a partial exploded view of an embodiment including the glass, IR absorbing film, unilaterally thermally conductive material and at least one thermoelectric generator (“TEG”). In the preferred embodiment, at least one piece of float glass (1) was used, but any other transparent substrate can be used. First, the surface of the float glass was prepared and primed. An important part the application procedure of an infrared absorbing coating is surface preparation. The surface was degreased and cleaned, leaving behind a contaminant free substrate for an infrared absorbing material to be applied. DryWired® LNT Primer was used to clean the glass with a nonwoven gauze-like material to wipe the float glass substrate to clean and prime the surface. DryWired® LNT Primer is a primer comprised of methanol (90%), Water (4%), Silicon Dioxide (2%), and Tin Oxide (0.1%) (percentages are given by weight), but other similar commercially available primers may be used.

Second, the infrared-absorbing film (2) was applied to the glass. In the preferred embodiment, DryWired® Liquid NanoTint® is used to coat the surface, but other commercially available infrared absorbing coating may be used. The Liquid NanoTint® is comprised of Cesium Tungstate (5%), 2-(2-Hydroxy-5-methylphenyl) benzotrazole (7%), 2-Butoxyethyl acetate (10% to 20%), propylene glycol monomethyl ether acetate (19%), Acrylic Resin (23% to 35%), and Butyl Acetate (23% to 35%) (percentages are given by weight). The 5% Cesium Tungstate Liquid NanoTint® is used in the preferred embodiment for greater IR absorption and increased electricity generation. Liquid NanoTint®, or other similar IR absorbing film or coating, may comprise 0% to 10% Cesium Tungstate. In addition to the IR absorbing coating, in this case DryWired® Liquid NanoTint®, Liquid NanoTint® Hardener (not shown) was also applied to the glass in a 9 to 1 ratio of Liquid NanoTint® to DryWired® Liquid NanoTint® Hardener. The DryWired® Liquid NanoTint® Hardener is comprised of Polyhexamethylene diisocyanate (75% to 85%) and DBE-5 Dibasic ester (1% to 25%) (percentages are given by weight). A high-density foam roller was used to apply each of the coating (film) and hardener. The Liquid NanoTint® and Liquid NanoTint® Hardener mixture can comprise a film between 10 to 20 microns in thickness once the mixture is dried. Although the mixture can be applied in greater quantities on glass or polycarbonate resulting in increased thickness, the resulting film looses transparency with increased thickness of the Liquid NanoTint® and Liquid NanoTint® Hardner mixture. Further, other commercially available IR absorbing films can be used which may or may not require a hardener to be applied, herein a single application IR absorbing film or a two-application film, comprising an IR absorbing film and hardener, may be referred to an IR absorbing film.

After the Liquid NanoTint® and Liquid NanoTint® Hardener were applied to make the IR-absorbing coating, the unilateral thermally conductive material (3) was placed over the coating. The unilateral thermally conductive material, more thermally conductive than the coating absorbing the solar heat energy, should be laid in the Liquid NanoTint® and Liquid NanoTint® Hardener mixture before the mixture is dry and in such a manner that at least one end of the thermally conductive material is positioned to connect to at least one TEG (4). The unilateral thermally conductive material will move thermal energy towards the TEG and allow for the TEG to generate more electricity. The unilateral thermally conductive material may or may not be transparent. In the preferred embodiment, graphene is the preferred the thermally conductive material, however, other thermally conductive materials can be used, such as carbon black, carbon nanotubes, metal oxides, metal wires, conductive inks and pastes, and other thermally conductive materials.

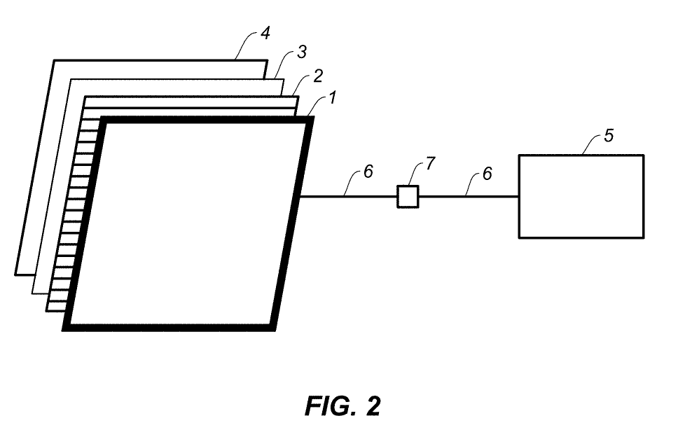

Applicant's FIG. 2 shows the preferred embodiment, wherein the IR absorbing film (2), the unilaterally conductive material (3), and the TEG (4) were dried and cured on glass (1) for 14 days at atmospheric conditions. Each thermoelectric generator (4) was located near an edge of the glass (1), however, thermoelectric generators may be placed at other locations on or about the glass. After the cure period, the TEGs were connected to electrically conductive wires (6) for transfer of electricity to a network for delivery of electricity to any device powered by electricity by traditional methods, such as metal wire or other conductive materials (not shown) or the thermoelectric generators may be connected to at least one electrical storage device, such as a rechargeable lithium ion battery (5). Devices powered by the energy harvested from the waste heat and converted to electricity by TEG may include free standing cooling devices (small fans, small cooling units), IoT devices or any other device that uses electricity. In the preferred embodiment, the electricity is transferred from at least one thermoelectric generator to an electricity storage device, such as a rechargeable battery, for later use. At least one lithium ion rechargeable battery is used in the preferred embodiment, but any rechargeable battery or other electrical storage device may be used. Advances in lithium ion rechargeable battery technologies have made battery storage for home use possible.

The TEG (4) must be connected to the IR coating in a thermally conductive manner. Two different means can be used to connect the TEG (4) to the thermally conductive material and the glass with the IR coating. The first requires the TEG to be attached onto the coating with conductive paste. The second involves laying the TEG in the wet coating and thereafter allowing the coating to dry. If coating has previously been applied, the thermoelectric device may be affixed on dry coating with conductive paste. In the preferred embodiment, at least one TEG is positioned at the edges of the glass and the heat receiving connection of the TEG is connected to at least one end of at least one thermally conductive material; however, the TEGs may be positioned anywhere about the glass. In another embodiment, the TEG is not located on the glass (or other substrate or fenestration used) while the heat receiving connection of the TEG is still connected to the IR coating by thermally conductive material(s).

In the preferred embodiment, the heat removal connection of the TEG was connected to a rechargeable battery storage device. (5) The TEG may or may not include a heat sink. The TEG may or may not be transparent. The storage device is commercially available. In another embodiment, the TEG is connected into outlet circuitry. In another embodiment, a commercially available thermal switch (7) to stop heat transfer from the thermoelectric generator to the IR absorbing film when the IR absorbing film is below a certain temperature may be installed between the TEG and the thermally conductive material or between the TEG and said electrical storage device. The thermal switch can be connected to a temperature sensor to automatically power on or off. The thermal switch can be manual. The thermal switch can also be set on a timer. The preferred method is one in which the sensor is connected to a temperature sensor.

### EXAMPLES

In an experiment testing various DryWired® Liquid NanoTint® and Liquid NanoTint® Hardener combinations, three versions of Liquid NanoTint® were used to test IR absorption, dissipation, and electrical generation capacity. Specifically, Liquid NanoTint®, Liquid NanoTint® Clear, and Liquid NanoTint® MTO were compared which contain different amounts of infrared absorbing metal oxides including cesium tungsten oxide (CTO) and Multi-doped Tin Oxide (SnO2). Versions of the DryWired® Liquid NanoTint® also included indium tin oxide, which is an IR reflector, to see the effect on the combination of IR absorbing and IR reflecting materials.

For the experimental setup, DryWired® Liquid NanoTint® Primer was applied with a nonwoven gauze like material to wipe the 6×6″ 3 mm float glass substrate to clean and prime the surface. Thereafter, DryWired® Liquid NanoTint® was then used to coat one surface of the float glass and was applied with a high-density foam roller. The coated float glass was cured for 14 days at atmospheric conditions. A TEG was then attached to the float glass using a conductive paste and positioned adjacent and connected to the IR-absorbing film. The TEG used was a TEC1-12706 Thermoelectric Peltier Cooler 12 Volt 92 Watt. The TEG was also connected to a voltmeter, opposite the TEG and IR-absorbing film connection. The voltmeter had positive and negative leads. A thermocouple was placed on the glass to measure the temperature of glass itself. The increase in temperature over time measures the absorption of the infrared energy by the metal oxides. The decrease in temperature over time measures the dissipation of the infrared energy of the metal oxides. A 500 watt heat lamp was positioned 12 inches from the 6×6″ piece of 3 mm float glass coated with the IR-absorbing material and connected to the TEG and voltmeter. For the experiment, time, temperature of the glass, and voltage generated from the TEG were measured and recorded. The experiment was run for 300 seconds. The heat lamp was turned on at 0 seconds. The heat lamp was turned off when the material reached 65 C.

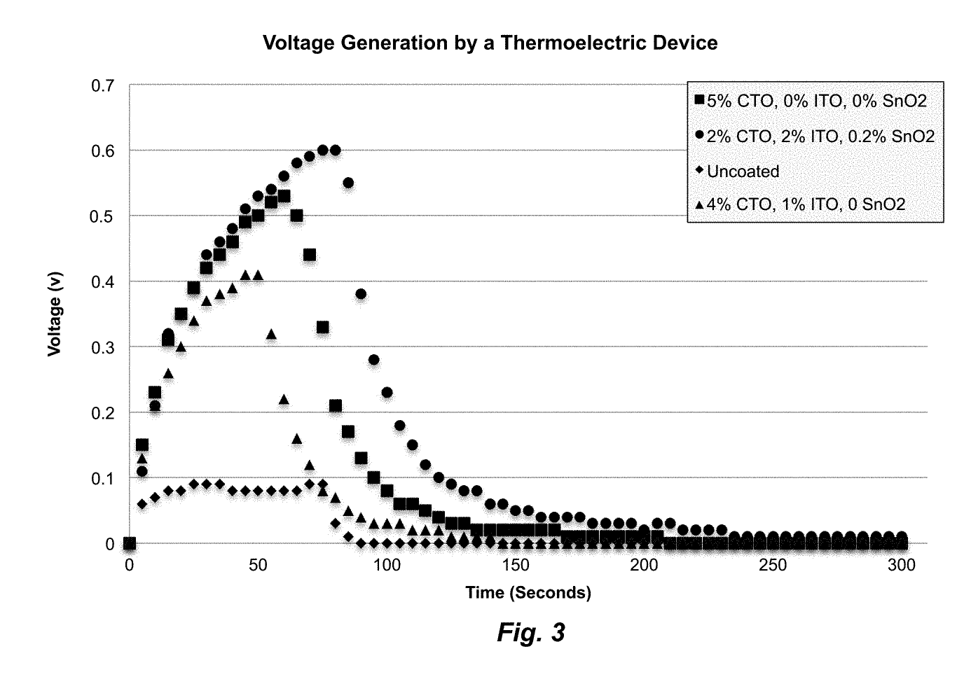

The voltage generation by a thermoelectric device is shown in FIG. 3. Applicant's FIG. 3 shows that all embodiments of the DryWired® Liquid NanoTint® film on glass and attached to a TEG exhibited a greater voltage generation than the uncoated 3 mm float glass, with the highest voltage generating material was 2.0% ITO, 2.0% CTO, and 0.2% SnO2 at 0.6 Volts.

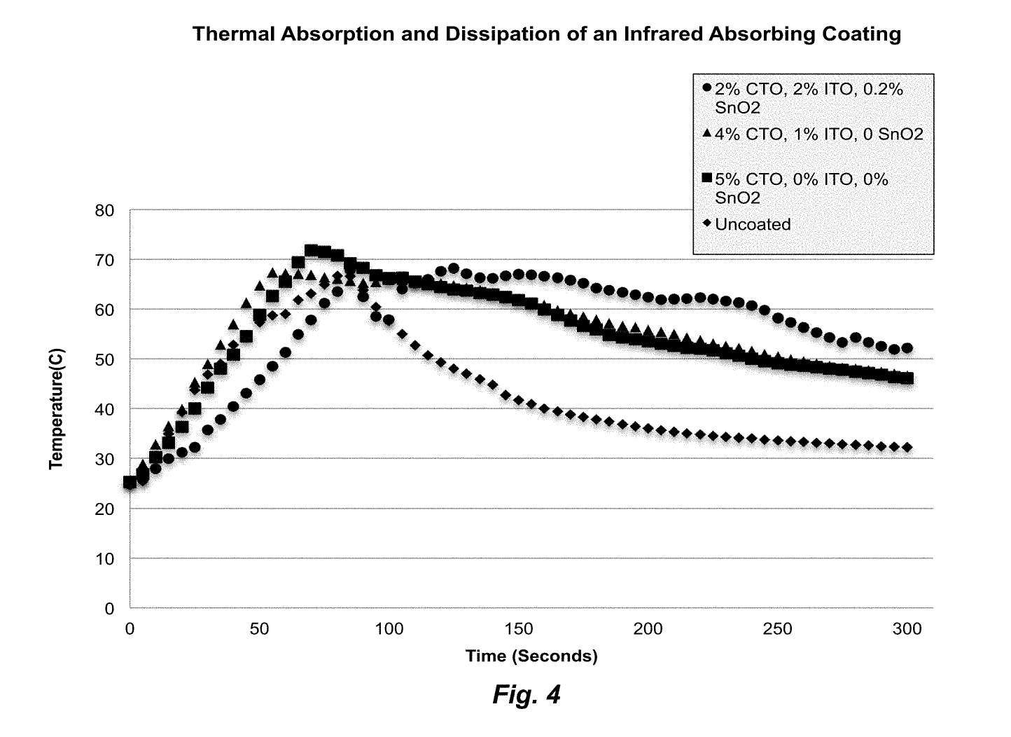

Applicant's FIG. 4 represents the amount of thermal energy absorbed by the infrared absorbing material by indication of temperature, as well as demonstrating how quickly this infrared energy dissipates. All samples were removed from infrared energy after the temperature of the surface reached 65 C. The version of Liquid NanoTint® that absorbed the infrared energy the most quickly was the 4.0% CTO, 1.0% ITO, and 0.0% SnO2. The Liquid NanoTint® version that absorbed the least quickly was the material containing 2.0% CTO, 2.0% ITO, and 0.2% SnO2.

In an embodiment, an infrared thermoelectric insulating power generator comprises an infrared absorbing film applied to a fenestration and a thermoelectric generator with a heat receiving connection and a heat removal connection opposite the heat receiving connection, said heat receiving connection attached to said infrared absorbing film. The thermoelectric generator may comprise a plurality of thermoelectric generators. The thermoelectric generator heat removal connection may be connected to at least one electricity-consuming device or may be connected to at least one electrical storage device. Finally, the embodiment may have a thermal switch connected with electrical conductive material between said electrical storage device and said thermoelectric generator.

In another embodiment, an infrared thermoelectric insulating power generator comprises an infrared absorbing film applied to a fenestration, at least one thermally conductive material connected to said infrared absorbing film and a thermoelectric generator with a heat receiving connection and a heat removal connection, said heat receiving connection connected to said at least one thermally conductive material. The thermoelectric generator may comprise a plurality of thermoelectric generators. The thermoelectric generator heat removal connection may be connected to at least one electricity-consuming device or may be connected to at least one electrical storage device. The embodiment may have a thermal switch connected with electrical conductive material between said electrical storage device and said thermoelectric generator. Finally, the embodiment containing a thermal switch may be connected to a temperature sensor, a timer, or may be controlled manually.

In still another embodiment, an infrared thermoelectric insulating power generator comprises an infrared absorbing film applied to glass and a thermoelectric generator with a heat receiving connection and a heat removal connection opposite the heat receiving connection, said heat receiving connection attached to said infrared absorbing film. The thermoelectric generator may comprise a plurality of thermoelectric generators.

The thermoelectric generator heat removal connection may be connected to at least one electricity-consuming device or may be connected to at least one electrical storage device. Finally, the embodiment may have a thermal switch connected with electrical conductive material between said electrical storage device and said thermoelectric generator.

In yet another embodiment, an infrared thermoelectric insulating power generator comprises an infrared absorbing film applied to a substrate with high visible light transfer, at least one thermally conductive material connected to said infrared absorbing film, and a thermoelectric generator with a heat receiving connection and a heat removal connection, said heat receiving connection connected to said at least one thermally conductive material. The thermoelectric generator may comprise a plurality of thermoelectric generators. The thermoelectric generator heat removal connection may be connected to at least one electricity-consuming device or may be connected to at least one electrical storage device. Finally, the embodiment may have a thermal switch connected with electrical conductive material between said electrical storage device and said thermoelectric generator. In another embodiment, each thermally conductive material of the plurality of thermally conductive material is connected to at least one thermoelectric generator.

In still yet another embodiment, an infrared thermoelectric insulating power generator comprises an infrared absorbing film applied to a surface with high visible light transfer, at least one thermally conductive material connected to said infrared absorbing film, a thermoelectric generator with a heat receiving connection and a heat removal connection, said heat receiving connection connected to said at least one thermally conductive material, and a thermal switch connected with electrical conductive material between said electrical storage device and said thermoelectric generator.

Upon reading this disclosure, those of skill in the art will appreciate still additional alternative structural and function designs for an infrared thermoelectric power generator. Thus, while particular embodiments and applications have been illustrated and described, it is to be understood that the disclosed embodiments are not limited to the precise construction and components disclosed herein. Additionally, variants of additional embodiments are possible. Therefore, the spirit and scope of the appended claims and the concepts taught herein should not be limited to the description of the preferred embodiments and embodiments contained herein.

1. An infrared thermoelectric insulating power generator, comprising:
a. An infrared absorbing film applied to a fenestration;
b. A thermoelectric generator with a heat receiving connection and a heat removal connection opposite the heat receiving connection, said heat receiving connection attached to said infrared absorbing film.

2. The infrared thermoelectric insulating power generator of claim 1, wherein said thermoelectric generator comprises a plurality of thermoelectric generators.

3. The infrared thermoelectric insulating power generator of claim 1, wherein said thermoelectric generator heat removal connection is connected to at least one electricity-consuming device.

4. The infrared thermoelectric insulating power generator of claim 1, wherein said thermoelectric generator heat removal connection is connected to at least one electrical storage device.

5. The infrared thermoelectric insulating power generator of claim 4, further comprising a thermal switch connected with electrical conductive material between said electrical storage device and said thermoelectric generator.

6. An infrared thermoelectric insulating power generator, comprising:
a. An infrared absorbing film applied to a fenestration;
b. At least one thermally conductive material connected to said infrared absorbing film;
c. A thermoelectric generator with a heat receiving connection and a heat removal connection, said heat receiving connection connected to said at least one thermally conductive material.

7. The infrared thermoelectric insulating power generator of claim 6, wherein said thermoelectric generator comprises a plurality of thermoelectric generators.

8. The infrared thermoelectric insulating power generator of claim 6, wherein said thermoelectric generator heat removal connection is connected to at least one electricity-consuming device.

9. The infrared thermoelectric insulating power generator of claim 6, wherein said thermoelectric generator heat removal connection is connected to at least one electrical storage device.

10. The infrared thermoelectric insulating power generator of claim 9, further comprising a thermal switch connected with electrical conductive material between said electrical storage device and said thermoelectric generator.

11. An infrared thermoelectric insulating power generator, comprising:
a. An infrared absorbing film applied to transparent substrate;
b. A thermoelectric generator with a heat receiving connection and a heat removal connection opposite the heat receiving connection, said heat receiving connection attached to said infrared absorbing film.

12. The infrared thermoelectric insulating power generator of claim 11, wherein said thermoelectric generator comprises a plurality of thermoelectric generators.

13. The infrared thermoelectric insulating power generator of claim 11, wherein said thermoelectric generator heat removal connection is connected to at least one electricity-consuming device.

14. The infrared thermoelectric insulating power generator of claim 11, wherein said thermoelectric generator heat removal connection is connected to at least one electrical storage device.

15. The infrared thermoelectric insulating power generator of claim 14, further comprising a thermal switch connected with electrical conductive material between said electrical storage device and said thermoelectric generator.

16. An infrared thermoelectric insulating power generator, comprising:
a. An infrared absorbing film applied to substrate with high visible light transfer;
b. At least one thermally conductive material connected to said infrared absorbing film;
c. A thermoelectric generator with a heat receiving connection and a heat removal connection, said heat receiving connection connected to said at least one thermally conductive material.

17. The infrared thermoelectric insulation power generator of claim 16, wherein said at least one thermally conductive material is a plurality of thermally conductive materials.

18. The infrared thermoelectric insulating power generator of claim 16, wherein said thermoelectric generator comprises a plurality of thermoelectric generators.

19. The infrared thermoelectric insulation power generator of claim 17, wherein each said thermally conductive material of said plurality of thermally conductive material is connected to at least one thermoelectric generator.

20. The infrared thermoelectric insulating power generator of claim 16, wherein said thermoelectric generator heat removal connection is connected to at least one electricity-consuming device.

21. The infrared thermoelectric insulating power generator of claim 16, wherein said thermoelectric generator heat removal connection is connected to at least one electrical storage device.

22. The infrared thermoelectric insulating power generator of claim 21, further comprising a thermal switch connected with electrical conductive material between said electrical storage device and said thermoelectric generator.

23. An infrared thermoelectric insulating power generator, comprising:
a. An infrared absorbing film applied to a surface with high visible light transfer;
b. At least one thermally conductive material connected to said infrared absorbing film;
c. A thermoelectric generator with a heat receiving connection and a heat removal connection, said heat receiving connection connected to said at least one thermally conductive material;
d. A thermal switch connected to the heat removal connection.

24. The infrared thermoelectric insulating power generator of claim 24, where said thermoelectric generator comprises a plurality of thermoelectric generators.
